(19) United States
(12) Patent Application Publication
(10) Pub. No.: US 2007/0158188 A1
(43) Pub. Date: Jul. 12, 2007

(54) Metal foam shield for sputter reactor

(76) Inventor: Eugene Y. Ivanov, Grove City, OH (US)

Correspondence Address: WEGMAN, HESSLER & VANDERBURG, 6055 ROCKSIDE WOODS BOULEVARD, SUITE 200, CLEVELAND, OH, 44131, US

(21) Appl. No.: 11/587,450

(22) PCT Filed: Jun. 1, 2005
(86) PCT No.: PCT/US05/19194

§ 371 Date: Oct. 24, 2006

Related U.S. Application Data
(60) Provisional application No. 60/579,745, filed on Jun. 15, 2004.

(51) Int. Cl. C23C 14/00

(52) U.S. Cl. 204/298.02

(57) ABSTRACT

A shield (22) for protecting chamber walls (14) of a sputter reactor (10) comprising foam metal shaped into a desired shield shape. The foam metal inserts (24) are easily configured for mounting within the sputter reactor chamber. The foam metal shield material provides more surface area and better adhesion of the sputter coated particles, thereby reducing particulate emission and allowing longer use before replacement. The shields are also relatively inexpensive to fabricate. Once the shield is coated with sputter particles, the foam metal shield can be removed from the sputter chamber and heated in a thermite reaction, thereby reducing the particles collected on the foam metal shield to an elemental metal and thus facilitating recovery of the deposited sputter material. The apparatus has a target (12), vacuum pump (21), pedestal (18), substrate (16), gas supply system (20), clips (25), insulating ring (26), DC power supply (24), and metal layer (28).

### CROSS REFERENCE TO RELATED APPLICATION

Priority benefit of U.S. Provisional Application Ser. No. 60/579,745 filed on Jun. 15, 2004 is hereby made.

### FIELD OF THE INVENTION

The invention relates generally to sputter deposition of materials. In particular, the invention relates to a shield used in a sputter reactor.

### BACKGROUND OF THE INVENTION

Sputtering, alternatively called physical vapor deposition (PVD), is the most prevalent method of depositing layers of metals and metal nitrides in the fabrication of silicon integrated circuits and flat panel displays. The sputtering process not only coats the workpiece with the sputtered metal atoms, it also coats any other body exposed to the target, such as the chamber wall of the sputtering system. Cleaning sputtered material from the interior of the chamber wall is difficult and time consuming. Accordingly, it is standard practice to include sputter shields, typically formed of aluminum or stainless steel, which protect the chamber wall from sputter deposition by intercepting sputtered material before it is coated on the chamber wall. As a result, the shields themselves are instead coated with the sputtered material. When the shields become excessively coated to the point that the coating tends to flake and produce deleterious particles, they are replaced with fresh shields in a preventative maintenance procedure. Unfortunately, before they are replaced, particulate ejections from the shield often land on the desired substrate and adversely affect coating uniformity and substrate conformity with particulate content specifications.

Typically, the shields are simply discarded, or they are cleaned off line, perhaps mechanically or by immersion in a cleaning solution, resulting in dissolution of the sputter material from the shield structure. Such known maintenance procedures are costly and time consuming, resulting in both system downtime and the loss of substantial amounts of sputter material deposited on the shields.

### SUMMARY OF THE INVENTION

A shield for protecting chamber walls and other parts of a sputter reactor comprising a foam metal. In one particular embodiment, one or more layers of foam metal inserts are formed into a desired shield shape. In another embodiment, the foam metal configuration includes one side covered with a solid metal layer so that the foam metal inserts may be mounted to solid metal parts of a preexisting shield structure with the foam metal layer facing the interior of the sputter chamber. The foam metal inserts may also comprise at least one attachment means, such as a clip for clipping the foam metal inserts to the preexisting shield structure, thus allowing new foam inserts to be used when it becomes necessary to change or replace the shield. In another embodiment, the entire shield structure itself is formed from the foam metal material, with the complete foam metal structure being mounted within the sputter chamber.

In any case, the foam metal shield material provides increased surface area and better adhesion of the sputter coated particles, thereby reducing particulate emission and allowing longer use of the shield before replacement. The foamed metal shields are also relatively inexpensive to fabricate. In another aspect of the invention, an exemplary foam metal shield for use in ITO (indium-tin-oxide) sputtering of flat panel displays comprises an aluminum foam metal material, preferably of the type sold under the designation Duocel® available from ERG Materials and Aerospace Corporation of Oakland, Calif. When the shield is replaced, it is heated in a thermite reaction, thus reducing the particles collected on the foam metal shield to elemental indium and facilitating recovery of the deposited sputter material.

### BRIEF DESCRIPTION OF THE DRAWINGS

FIG. 1 is a schematic cross-sectional view of a sputter reactor including a shield in accordance with an embodiment of the invention; and

FIG. 2 is a magnified view showing the open-cell structure of the foam metal shield of the invention.

### DETAILED DESCRIPTION OF THE INVENTION

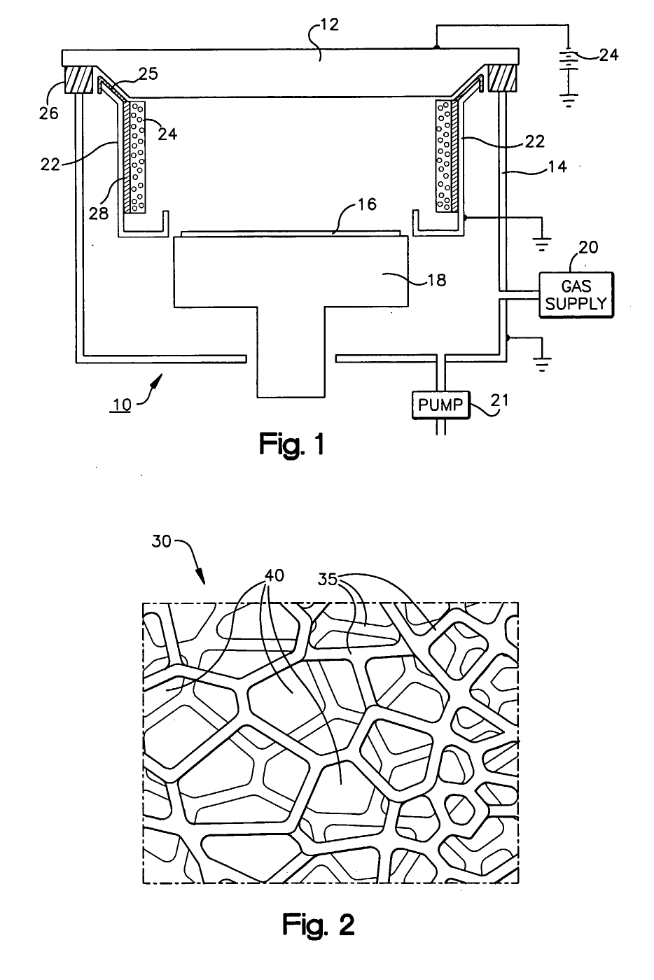

In modern fabrication of semiconductor integrated circuits and flat panel displays, metals are typically deposited by physical vapor deposition (PVD) utilizing a plasma reactor 10 of the type illustrated in the schematic cross section of FIG. 1. This reactor 10 includes a PVD target 12, which in conjunction with a chamber wall 14 and other sealing members, forms a vacuum chamber. The PVD target 12 is comprised, at least the portion facing the central portion of the vacuum chamber, of the material to be sputtered. A substrate 16 whose surface is to be sputter deposited is supported on a pedestal 18 positioned in opposition to the target 12. A gas supply system 20 supplies a controlled flow of various gases into the vacuum chamber while a vacuum pump 21 maintains a vacuum level at a fixed gas flow. The conductive chamber wall 14, usually made of aluminum or stainless steel, is generally grounded while a DC power supply 24 applies a negative voltage of about =500V to the target 12. An insulating ring 26 between the target 12 and the chamber wall 14 allow their differential biasing. The electrical bias causes the argon to discharge and form a plasma of positively charged argon ions and negatively charged electrons in the space between the target 12 and the substrate 16. The argon ions are electrically attracted to the negatively charged target 12 and, strike it at high enough energy to sputter target particles from the target 12. In order to prevent a sizeable fraction of the particles from hitting the chamber walls 14 and becoming deposited thereon, one embodiment of the present invention provides a sputter shield comprising one or more layers of foam metal inserts 24 for use within the plasma reactor 10. As shown in FIG. 1, the foam metal inserts 24 may comprise an attachment means such as one or more clips 25 for clipping the foam metal inserts 24 onto a preexisting shield structure 22. The insert 24 can also be removably mounted to structure 22 by other conventional means such as being bottled, screwed, or welded to the structure 22. The foam metal configuration 24 may also include a solid metal layer 28 to facilitate mounting of the foam metal inserts 24 to the shield structure. The layer 28 may be welded or itself clipped to the metal foam insert 24. Alternatively, it is noted that the present invention contemplates forming the entire shield structure from foam metal material.

The foam metal inserts 24 are easily configured into a desired shield shape, for example, by cutting and shaping the foam metal material so that the inserts 24 intersect any direct path between the target 12 and the chamber wall 14. In this way, sputter particles traveling toward the chamber wall 14 are collected by the foam metal inserts 24 instead of becoming deposited on the chamber wall 14.

In accordance with the present invention, a sputtering shield can be advantageously formed at least in part by one or more layers of foam metal. A magnified view of an exemplary foam material 30 is shown in FIG. 2. For purposes of providing a shield specifically for ITO (indium-tin-oxide) sputter reactors, the foam metal material advantageously comprises aluminum. One exemplary type of foam metal material is sold under the designation Duocel® and is available from ERG Materials and Aerospace Corporation in Oakland, Calif. This exemplary aluminum foam material is available in a density range from about 3%-12% uncompressed and can be compressed up to 60% dense relative to the solid base metal, and is available in standard pore sizes including 5, 10, 20, and 40 pores per linear inch (ppi). The pore sizes can be adjusted independently or by varying the relative density. Foam properties can be tailored for a specific application and material response by adjusting the foam density, pore size, alloy, and ligament structure. Processes for making the foams are disclosed for example in U.S. Pat. No. 3,616,841 and 3,946,039, the disclosures of which are incorporated by reference herein.

Advantageously, the open-celled nature of the metal foam provides a combination of properties suitable for use as a sputtering shield. For example, the open-celled nature of the foam metal shield provides more surface area and better adhesion of sputter coated layers, allowing the shield to collect virtually all sputtered particles passing through it. The use of multiple layers of foam material in constructing the foam metal inserts 24 results in a larger effective surface area for the collection of sputter coated materials, thus improving the overall effectiveness of the shield structure.

Referring again to FIG. 2, the exemplary metal foam material consists of small ligaments 35 continuously connected in an open-celled foam structure. The cells 40 are generally 12-14 sided polyhedra whose pentagonal or hexagonal faces are formed by five or six ligaments. Two characteristics, pore size and relative density, are generally adequate to specify the foam material for a particular application. The pore diameter is expressed in terms of pores per linear inch (ppi), and generally falls within the range of about 5 to about 100 ppi. Pore size determines certain foam characteristics such as specific surface area, fluid flow resistance, and optical capacity.

The foam material also defines a relative density, which is defined in terms of a percentage (%) of a solid; that is, the volume of foam material relative to the volume of material in a solid block of the base material. As relative density is increased, the ligaments become larger in diameter and stronger, increasing the strength of the foam structure. Relative density is the primary determinant of foam stiffness, strength, and both electrical and thermal conductivity.

In ITO (indium-tin-oxide) sputtering of flat panel displays, a substantial amount of ITO particles become adhered to the aluminum foam metal shield. As mentioned above, the foam metal material provides better adhesion of the sputter coated particles. Moreover, since the foam metal shield comprises a reactant such as aluminum, the inserts 24 may be used in a thermite reaction wherein the spent foam metal shield is heated to thereby reduce the particles collected thereon to an elemental metal (i.e. indium), thus facilitating recovery of the deposited sputtered material for further use. Those skilled in the art understand that a thermite reaction is one in which aluminum metal is oxidized by an oxide of another metal. The products of a thermite reaction are typically aluminum oxide, the free elemental metal, and a great amount of heat. Therefore, in one exemplary embodiment, the present invention involves using a foam metal insert, for example an aluminum foam metal insert, as a reactant in a thermite reaction, thereby, upon heating, reducing the material collected on the inserts 24 to an elemental metal, for example indium, thus facilitating recovery of the deposited ITO sputtered material for further use.

The invention will be further illustrated by the following example which should not be construed as a limitation to the invention as defined in the claims.

### EXAMPLE

The object was to determine if an Al foam metal could be useful in reducing shield flaking in a DC Magnetron Sputter system.

One of the major issues today in sputtering is particles ending up on the substrates being coated. One of the sources of these particles is the stainless steel shielding that is used in the sputtering chamber. As the sputtered material builds up on the shielding a lot of stress builds in the film. At a point the film stress will exceed the film adhesion and the film will start to flake off the shielding. We have been experimenting with replacing the stainless shielding with Al foam metal shields to breakup the film stress and stop the film from flaking.

For our experiments we used a sputtering system that had a 13 inch diameter Ta planar target installed in the process chamber. We chose Ta due to the problems we have had with a lot of flaking from the stainless steel shielding. The stainless steel dark space shield is very close to the sputter target and does a lot of flaking. So on the dark space shield we removed half of the stainless steel and put the Al foam metal sheet in its place. Since this sheet is so open we had to put a thin piece of SS in back of the foam metal sheet. This was done to protect the chamber walls from sputtered material getting through the sheet to the walls. The substrate table was covered with a large diameter SS plate so we could capture the amount and location of any flaking. All of this was installed into the chamber and pumped down to a typical vacuum of 4.0×10⁻⁷ torr. The Ta target was sputtered for 50 kWhrs then allowed to cool overnight before we opened the chamber.

When we opened the chamber you could see a lot of flaking and particles on the half of the substrate table that was nearest to the SS dark space shield. On the half by the Al foam metal sheet there was very little evidence of flakes or particles. The few that were seen probably came from the SS side. When the dark space shield was removed Ta was found on the SS sheet that was in back of the Al foam metal sheet. The Ta sputtered through the Al foam metal sheet and deposited on the SS sheet. There were very fine particles lying in the bottom of the chamber. When the SS sheet was examined we could see where the Ta was coming off this sheet even after removing it from the dark space shield. The examination of the Al foam metal sheet by optical microscope showed no signs of flaking.

Although the invention has been described primarily with an Al foam metal shield, the artisan will appreciate that a host of other foam metal and metal alloy materials may be used in accordance with the invention. For example, Mg, Zn, Cu, Fe, Ni, Ag, or stainless can also be mentioned as well as their alloys as metal foam materials that may be used as a sputter chamber shield in accordance with the invention.

While the present invention has been described with reference to exemplary embodiments thereof, it is understood that those of ordinary skill in the art may make certain additions or modifications to, or deletions from, the described present embodiments of the invention without departing from the spirit or scope of the invention, as set forth in the appended claims.

What is claimed is:

1. A sputter shield for protecting the walls of a sputter reactor from sputter deposition, said shield being removably attached to said reactor and comprising a foamed metal or alloy.

2. Sputter shield as recited in claim 1 further comprising a metal sheet material attached to said foamed metal or alloy, and serving as a backing structure for said foamed metal or alloy and located intermediate said reactor and said foam metal or alloy.

3. Sputter shield as recited in claim 1 wherein said foamed metal or metal alloy comprises Al.

4. Sputter shield as recited in claim 3 wherein said foamed metal or metal alloy has an open celled structure with a pore size of about 5 to about 100 pores per inch.

5. A sputter shield for protecting walls of a sputter reactor, said sputter shield comprising a foam metal insert removably affixed within said sputter reactor for collecting sputtered particles from said sputter reactor, said foam metal insert comprising a reactant for use in a thermite reaction to reduce particles collected on said foam metal insert to an elemental metal.

6. The sputter shield of claim 5, wherein said reactant is aluminum and said collected particles are ITO (indium-tin-oxide) particles.

7. The sputter shield of claim 6, wherein said reactor comprises a preexisting shield structure, and said reactor further comprises attachment means for removably mounting said foam metal insert to said preexisting shield structure.

8. The sputter shield as recited in claim 7 wherein said attachment means comprises at least one clip.

9. The sputter shield of claim 6, wherein said reactor comprises a preexisting shield structure, and wherein said foam metal insert further comprises a metal layer for mounting said foam metal insert to said preexisting shield structure.

10. A method of recovering sputtered particles from a sputter reactor, comprising the steps of:
(a) providing a foam metal shield for protecting walls of said sputter reactor;
(b) collecting sputtered particles from said sputter reactor with said foam metal shield;
(c) heating said foam metal shield to reduce said collected sputtered particles by a thermite reaction to form an elemental metal representing said collected particles.

11. The method of claim 10, wherein said foam metal shield is an aluminum foam metal shield, and said collected sputtered particles are ITO (indium-tin-oxide) particles.

12. The method of claim 11, wherein said reactor comprises a preexisting shield structure, said method further comprising the step of detachably mounting said foam metal shield to said preexisting shield structure.
